(19) United States
(12) Patent Application Publication
(10) Pub. No.: US 2026/0214835 A1
(43) Pub. Date: Jul. 23, 2026

(54) Heat Dissipation Structure Featuring Fan and Heat Sink for Optimized Airflow

(71) Applicants: Kaiming Cao, Dongguan City (CN); Zhenhua Lin, Dongguan City (CN); Na Li, Dongguan City (CN)

(72) Inventors: Kaiming Cao, Dongguan City (CN); Zhenhua Lin, Dongguan City (CN); Na Li, Dongguan City (CN)

(21) Appl. No.: 19/026,396

(22) Filed: Jan. 17, 2025

(51) Int. Cl. H05K 7/20

(52) U.S. Cl. CPC H05K 7/20172; H05K 7/2039

(57) ABSTRACT

A heat dissipation structure for optimizing airflow by pairing a fan and a heat sink. The structure includes a fan, a circuit board, and a supporting housing. The fan is provided with a latch portion that mates with and fixes onto the circuit board. The circuit board has a latch hole corresponding to the latch portion, and further includes a conductor wire for power connection. The fan is additionally equipped with a conduction portion that makes electrical contact with the circuit board. By rapidly coupling the latch portion of the fan with the latch hole on the circuit board, assembly is greatly simplified, while the conduction portion contacts the circuit board for powering the fan. This design particularly facilitates ease of installation and removal in multi-fan applications, as no cabling is required and any single fan can be replaced quickly, thereby satisfying user demands for simple, self-service fan swaps.

### FIELD OF THE INVENTION

The present invention relates to the technical field of heat sinks, and more particularly to a heat dissipation structure in which a fan and a heat sink are paired to optimize airflow performance.

### BACKGROUND OF THE INVENTION

As the performance of electronic devices continues to increase, the power consumption and heat generation of their internal hardware also grow correspondingly. This is especially true in computing devices, servers, smartphones, automotive electronics, and industrial equipment, where the electronic components generate significant amounts of heat during operation. If such heat is not dissipated promptly and effectively, it may lead to decreased performance, hardware damage, and even potential safety hazards. Therefore, heat dissipation is a key factor in ensuring the stable operation of electronic devices. Fans used in conjunction with heat sinks play a major role in accelerating the removal of heat by forced convection. Typically, a metal heat sink absorbs heat from the heat source, while the fan provides airflow through its rotation to remove accumulated heat and expel it outside the device.

The efficiency of a cooling fan depends on factors such as its rotational speed, size, blade design, and airflow. A high-efficiency cooling fan can transfer heat rapidly through large airflow volume and carefully designed blades, while also reducing noise. For example, Chinese Patent Authorization No. CN202391779U discloses a fan structure that can be quickly disassembled. In the disclosed scheme, a fan bracket 1 is connected to a fan frame 2, and a heat sink 3 is mounted on the opposite side of the fan bracket 1. Multiple latching flanges 202 are spaced around the outer circumference of fan frame 2, and corresponding latch seats 101 that match the latching flanges 202 are provided at corresponding positions on fan bracket 1. Similar to this patent disclosure, most commercial cooling fans employ a fan frame 2 for support. However, the supporting plate within the fan frame 2 can obstruct airflow. Accordingly, optimizing the supporting structure can improve the heat dissipation efficiency of the cooling fan.

In view of the foregoing, the present inventors have proposed the following technical solution.

### SUMMARY OF THE INVENTION

The primary objective of the present invention is to overcome the shortcomings of the prior art by providing a heat dissipation structure in which a fan and heat sink are configured to optimize airflow performance.

To achieve the above objective, the present invention adopts the following technical solution: A heat dissipation structure featuring a fan and heat sink for optimized airflow performance, comprising a fan, a circuit board, and a supporting housing. The fan is provided with a latch portion that mates with and is fixed to the circuit board. The circuit board has a latch hole corresponding to the latch portion. The circuit board is also provided with a conductor wire for connection to a power source. The fan is further provided with a conduction portion that makes electrical contact with the circuit board.

In a further aspect of the above technical solution, the supporting housing is provided with multiple installation positions for holding the fan. The circuit board extends through each of these installation positions. Each installation position has a latch hole for engaging the fan, and a conductive region located adjacent to each latch hole for making electrical contact with the conduction portion on the fan.

In another further aspect, a first mounting hole is arranged on the periphery of each installation position of the supporting housing for fixing the circuit board. The circuit board is secured to the first mounting hole using screws or a latch.

In yet another aspect, the fan comprises fan blades, a connecting plate, and a driver, where the driver is located in a receiving cavity formed between the fan blades and the connecting plate. The fan blades are connected to the driver and the connecting plate in a manner allowing relative rotation. The latch portion is provided on the connecting plate, and the conduction portion is provided on the driver.

In another aspect, the connecting plate is disk-shaped, covering one end of the receiving cavity. The latch portion is situated in the middle of the connecting plate. The connecting plate is further provided with a mating hole through which the conduction portion extends to make electrical contact with the circuit board.

In a further aspect, the latch portion includes at least two resilient latching arms distributed symmetrically. The end of each resilient latching arm is provided with a protrusion that can pass through the latch hole and latch against the back side of the circuit board.

In yet another aspect, the latch portion comprises four resilient latching arms distributed around the circumference of the connecting plate at symmetrical intervals. The connecting plate is further provided with a first protrusion and a second protrusion for limiting and positioning the circuit board.

### Compared With the Prior Art, the Present Invention Offers the Following beneficial effects

In the present invention, the fan and circuit board can be quickly assembled or disassembled by means of an elastic latch portion on the connecting plate that engages the latch hole in the circuit board. Furthermore, the conduction portion on the driver contacts the circuit board without requiring additional cables, making assembly and disassembly more convenient, significantly improving production efficiency, and simplifying maintenance and replacement so that it can be performed by any user.

The present invention uses the latch portion on the fan to quickly engage with the circuit board, and the conduction portion on the fan to contact the circuit board to power the fan. This installation structure makes fan removal and replacement simpler and more convenient—especially when multiple fans are used—because it does not require cables, thereby enabling quick removal and replacement of any individual fan and meeting the needs of all users to replace fans on their own.

### BRIEF DESCRIPTION OF THE DRAWINGS

FIG. 1 is a first schematic view of the assembly structure of the present invention;

FIG. 2 is a second schematic view of the assembly structure of the present invention;

FIG. 3 is an exploded view of the present invention;

FIG. 4 is an enlarged partial view of region A in FIG. 1;

FIG. 5 is an exploded view of the fan of the present invention.

### DETAILED DESCRIPTION OF THE EMBODIMENTS

A more detailed explanation of the present invention is provided below in conjunction with specific embodiments and the accompanying drawings.

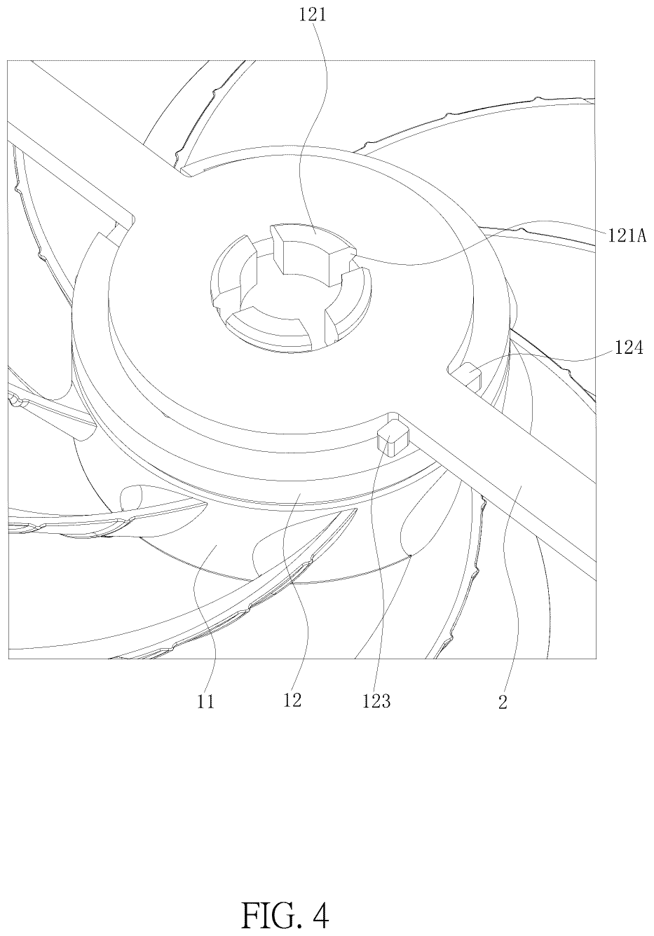

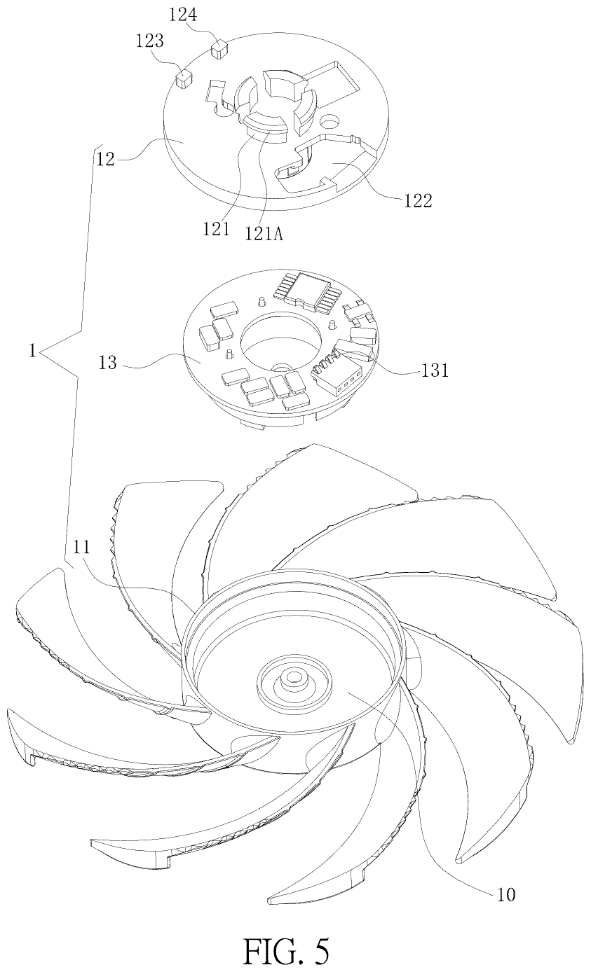

Referring to FIGS. 4 and 5, a first embodiment provides a cooling fan, which includes fan blades 11, a connecting plate 12, and a driver 13. The driver 13 is disposed in a receiving cavity 10, formed between the fan blades 11 and the connecting plate 12. The fan blades 11 are connected to the driver 13 and the connecting plate 12 in a manner allowing relative rotation. The connecting plate 12 is provided with a latch portion 121 that engages the circuit board 2, and the driver 13 is provided with a conduction portion 131 for contacting and conducting electricity with the circuit board 2. A micro motor for driving the rotation of fan blades 11 is arranged between the driver 13 and the connecting plate 12. By providing an elastic latch portion 121 on connecting plate 12 to engage with circuit board 2, the fan 1 can be quickly assembled with or disassembled from the circuit board 2. Moreover, by providing the conduction portion 131 on driver 13 so that it contacts the circuit board 2 directly, no extra wiring is required, thereby enhancing convenience in assembly and disassembly, significantly boosting production efficiency, and simplifying maintenance and replacement tasks, which can be performed by any user.

The connecting plate 12 is disk-shaped, covering one end of the receiving cavity 10. The latch portion 121 is located in the center of the connecting plate 12. The connecting plate 12 further has a mating hole 122, through which the conduction portion 131 passes to make electrical contact with circuit board 2. The receiving cavity 10 is provided at the center of the fan blades 11, and the driver 13 is mounted on connecting plate 12 to fix the micro motor. The fan blades 11 are mounted on the output shaft of the micro motor passing through the driver 13.

The circuit board 2 is provided with a latch hole 21 for engagement with the latch portion 121 of the fan. The circuit board 2 further includes a conductive region adjacent to latch hole 21 for contact with conduction portion 131. The latch portion 121 includes at least two symmetrically arranged resilient latching arms, each of which is provided at its free end with a protrusion 121A that extends through latch hole 21 and latches against the rear side of the circuit board 2. In the present embodiment, the latch portion 121 comprises four resilient latching arms distributed circumferentially and symmetrically. The connecting plate 12 is further provided with a first protrusion 123 and a second protrusion 124 for limiting and positioning the circuit board 2. With four resilient latching arms distributed symmetrically, the fan 1 can engage with the circuit board 2 in all four directions around the circumference, ensuring a stable connection. In addition, the first protrusion 123 and second protrusion 124 on connecting plate 12 facilitate accurate positioning of circuit board 2 on both sides, preventing relative rotation between connecting plate 12 and circuit board 2 once latched, and ensuring that the conduction portion 131 accurately contacts the conductive region on circuit board 2.

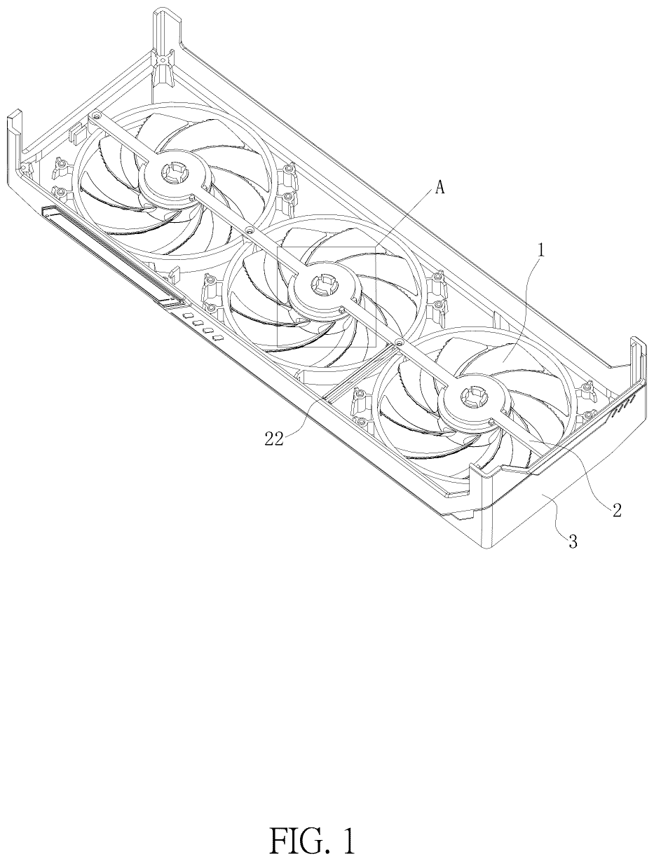

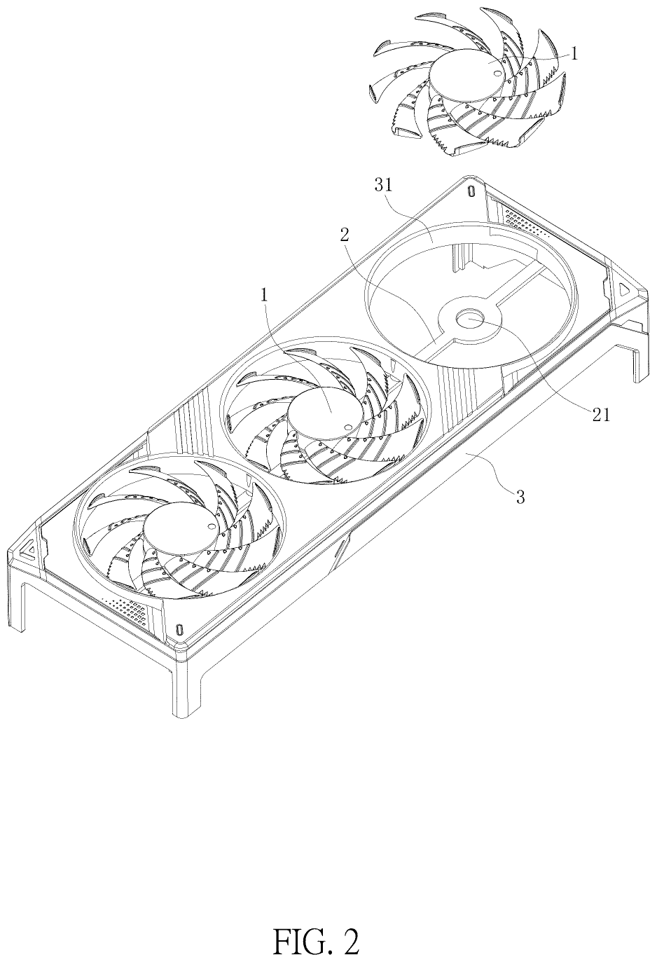

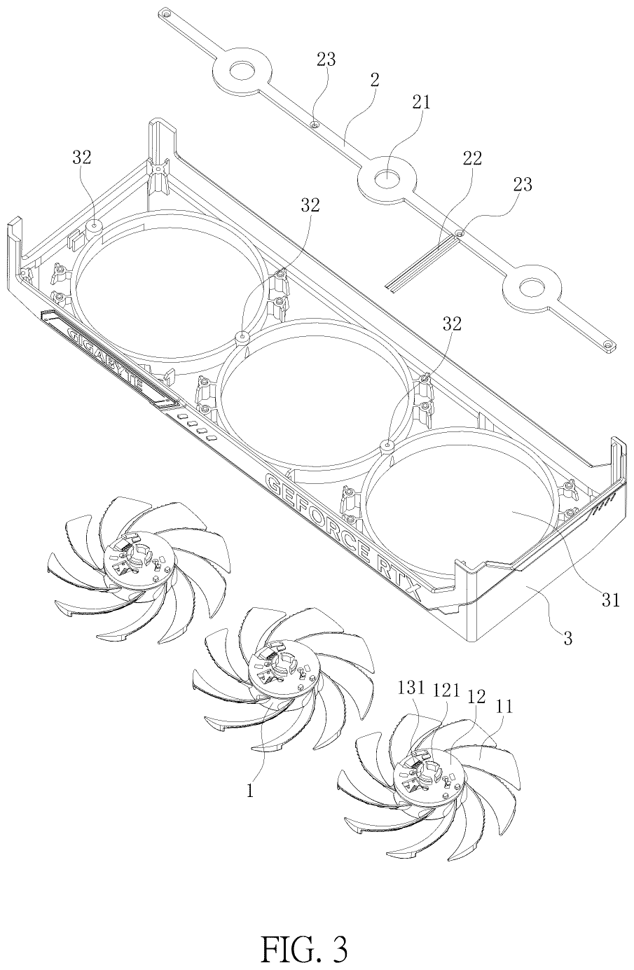

Referring to FIGS. 1 through 5, a second embodiment provides a heat dissipation structure in which a fan and heat sink are paired for optimized airflow, comprising a fan 1, a circuit board 2, and a supporting housing 3. The fan 1 is provided with a latch portion 121 for engaging and fixing to the circuit board 2. The circuit board 2 has a latch hole 21 that corresponds to the latch portion 121. The circuit board 2 is equipped with a conductor wire 22 for connection to a power source. The fan 1 is further provided with a conduction portion 131 that makes electrical contact with the circuit board 2. The fan 1 can be quickly mounted to circuit board 2 by means of the latch portion 121, and the conduction portion 131 on fan 1 contacts circuit board 2 for power, thus simplifying fan removal and replacement. This approach becomes especially advantageous when employing multiple fans, as no cabling is required for swapping out any individual fan, meeting user requirements for easy fan replacement.

The supporting housing 3 is provided with multiple installation positions 31 for holding the fan 1. The circuit board 2 extends through each of these installation positions 31. Each installation position 31 is furnished with a latch hole 21 for holding the fan 1, and a conductive region is located adjacent to each latch hole 21 for making electrical contact with the conduction portion 131. The circuit board 2 is formed in a strip shape and is provided with multiple annular board portions for interfacing with connecting plate 12. Each latch hole 21 is located in the center of one of these annular board portions. By installing multiple fans 1 in series on a single strip-shaped circuit board 2, each fan 1 can be independently assembled or disassembled, and airflow resistance can be minimized, enabling cooling air to pass through easily. The annular board portions also provide stable mounting and facilitate positioning between fan 1 and circuit board 2.

A first mounting hole 32 is arranged around each installation position 31 on supporting housing 3 for fixing circuit board 2. The circuit board 2 is attached to the first mounting hole 32 via screws or a latch. A second mounting hole 23 is formed in circuit board 2 at a corresponding location.

The fan 1 includes fan blades 11, connecting plate 12, and driver 13, where the driver 13 is disposed inside a receiving cavity 10 between fan blades 11 and connecting plate 12. The fan blades 11 are connected to the driver 13 and connecting plate 12 in a manner allowing relative rotation. The latch portion 121 is situated on connecting plate 12, while the conduction portion 131 is situated on driver 13. The latch portion 121 comprises four resilient latching arms arranged in a circumferentially symmetrical manner. The connecting plate 12 is further provided with a first protrusion 123 and a second protrusion 124 for limiting and positioning the circuit board 2.

In sum, in the present invention, a strip-shaped circuit board 2 is installed on supporting housing 3 to connect multiple fans 1 in series. By using the latch portion 121 on each fan 1 to engage with latch hole 21 of circuit board 2, quick assembly and disassembly can be achieved. Maintenance and replacement tasks can therefore be completed much faster. Moreover, electrical power is supplied via direct contact between conduction portion 131 on fan 1 and circuit board 2, replacing traditional cable connections. This arrangement not only makes the heat dissipator more organized but also reduces short-circuit risks. Additionally, compared to a traditional plastic bracket, the one-piece circuit board 2 can be made thinner, increasing the airflow passing into the heat sink to reduce wind resistance and improve the heat sink's efficiency.

It should be understood that the above descriptions merely illustrate certain exemplary embodiments of the present invention and do not limit its scope. Any modifications or variations that fall within the construction, characteristics, and principles described in the claims are intended to be included within the scope of the present invention.

What is claimed is:

1. A heat dissipation structure configured for optimizing airflow by pairing a fan and a heat sink, comprising:
a fan (1), a circuit board (2), and a supporting housing (3),
wherein the fan (1) is provided with a latch portion (121) for mating with and being fixed to the circuit board (2), the circuit board (2) is provided with a latch hole (21) corresponding to the latch portion (121), the circuit board (2) is provided with a conductor wire (22) for connection to a power source, and the fan (1) is provided with a conduction portion (131) for electrically contacting the circuit board (2).

2. The heat dissipation structure of claim 1, wherein the supporting housing (3) is provided with a plurality of installation positions (31) for receiving the fan (1), the circuit board (2) continuously passes through the plurality of installation positions (31), and each installation position (31) is provided with the latch hole (21) configured to secure the fan (1), each latch hole (21) having a conductive region adjacent thereto for making electrical contact with the conduction portion (131).

3. The heat dissipation structure of claim 1, wherein a first mounting hole (32) is arranged around a periphery of each installation position (31) for fixing the circuit board (2), and the circuit board (2) is secured to the first mounting hole (32) using either a screw or a latch.

4. The heat dissipation structure of claim 1, wherein the fan (1) comprises fan blades (11), a connecting plate (12), and a driver (13), the driver (13) being disposed within a receiving cavity (10) formed between the fan blades (11) and the connecting plate (12), the fan blades (11) being connected to the driver (13) and the connecting plate (12) in a manner allowing relative rotation, the latch portion (121) being provided on the connecting plate (12), and the conduction portion (131) being provided on the driver (13).

5. The heat dissipation structure of claim 4, wherein the connecting plate (12) is disk-shaped and covers one end of the receiving cavity (10), the latch portion (121) is situated at a central area of the connecting plate (12), and the connecting plate (12) further comprises a mating hole (122) through which the conduction portion (131) passes to establish electrical contact with the circuit board (2).

6. The heat dissipation structure of claim 4, wherein the latch portion (121) includes at least two resilient latching arms arranged symmetrically, and each resilient latching arm has an end portion provided with a protrusion (121A) that is configured to pass through the latch hole (21) and latch against a rear side of the circuit board (2).

7. The heat dissipation structure of claim 5, wherein the latch portion (121) comprises four resilient latching arms arranged in a circumferentially symmetrical manner, and the connecting plate (12) is further provided with a first protrusion (123) and a second protrusion (124) for limiting and positioning the circuit board (2).
